(19) United States
(12) Patent Application Publication
(10) Pub. No.: US 2013/0008486 A1
(43) Pub. Date: Jan. 10, 2013

(54) PHOTOELECTRIC CONVERSION ELEMENT MODULE

(75) Inventor: Akira Ono, Kanagawa (JP)

(73) Assignee: Sony Corporation, Tokyo (JP)

(21) Appl. No.: 13/494,182

(22) Filed: Jun. 12, 2012

(30) Foreign Application Priority Data
Jul. 4, 2011 (JP) 2011-148611

(51) Int. Cl. H01L 31/048; H01L 31/052

(52) U.S. Cl. 136/246; 136/244; 136/251

(57) ABSTRACT

Disclosed herein is a photoelectric conversion element module including a plurality of photoelectric conversion elements between two base materials. Each of the photoelectric conversion elements is anchored to one of the base materials via an anchoring layer. The anchoring layer covers at least part of a sealing portion of each of the photoelectric conversion elements.

### BACKGROUND

The present technology relates to a photoelectric conversion element module and, more particularly, to a photoelectric conversion element module in which a plurality of photoelectric conversion elements are housed in a housing body.

Among types of solar cells known in the past are crystalline solar cells, amorphous, compound semiconductor, thin film polycrystalline and organic solar cells. Recent years have seen attention focused on a dye sensitized solar cell as a potential substitute with low manufacturing cost for the above types of solar cells. This cell has a photoelectric conversion activating substance layer in which semiconductor particles hold a dye adapted to absorb visible light.

A solar cell may use a cell element module made up of a large number of cell elements connected together for a larger power generation area. As such a cell element module, one having two sheets of plate glass is proposed. These sheets of plate glass are laid one above the other with a spacer lying therebetween to form an internal space into which cell elements are fitted. Also proposed is the coverage of each of all the cell elements that are fitted into the internal space with a transparent filler for improved weather resistance of the cell elements (refer, for example, to Japanese Patent Laid-Open No. 2003-26455).

### SUMMARY

However, covering all the cell elements with a transparent filler as described above results in part of incident light being absorbed before reaching the incident sides of the cell elements. This leads to a reduced amount of light reaching the incident sides of the cell elements, thus resulting in reduced light utilization efficiency. Further, the transparent filler turns yellow and deteriorates due to ultraviolet rays contained in sunlight if made of an organic material, thus resulting in even lower light utilization efficiency.

In light of the above, it is desirable to provide a photoelectric conversion element module offering excellent weather resistance and light utilization efficiency.

According to an embodiment of the present technology, there is provided a photoelectric conversion element module including a plurality of photoelectric conversion elements between two base materials. Each of the photoelectric conversion elements is anchored to one of the base materials via an anchoring layer. The anchoring layer covers at least part of a sealing portion of each of the photoelectric conversion elements.

In the present technology, the photoelectric conversion element module is suitable for use as a construction member such as window material (e.g., window glass) and curtain wall. As a window material, eco-friendly glass such as multi-layered glass, laminated glass, Low-E glass or Low-E multi-layered glass is preferred. If applied to such eco-friendly glass, the photoelectric conversion element module should preferably include first and second glass plates and a sealant provided between the peripheral portions of the first and second glass plates.

In the present technology, the photoelectric conversion element should preferably have an incident side on which light falls, a rear side opposite to the incident side, and a lateral side provided between the peripheral portions of the incident and rear sides, with a sealing portion provided on the peripheral portion of the incident side, that of the rear side or the lateral side.

In the present technology, at least part of the sealing portion of the photoelectric conversion element is covered with an anchoring layer, thus reinforcing the sealing portion. Further, it is possible to suppress the entry of moisture into the photoelectric conversion element from the sealing portion. Still further, it is possible to expose the area contributing to power generation of all the surface of the photoelectric conversion element. Therefore, it is possible to suppress the reduction in amount of light reaching the area contributing to power generation.

As described above, the present technology provides a photoelectric conversion element module offering excellent weather resistance and light utilization efficiency.

### BRIEF DESCRIPTION OF THE DRAWINGS

FIG. 1A is a plan view illustrating a configuration example of a photoelectric conversion element module according to a first embodiment of the present technology, and FIG. 1B is a cross-sectional view along line IB-IB in FIG. 1A;

FIG. 2A is a cross-sectional view illustrating a configuration example of a photoelectric conversion element, and FIG. 2B is a cross-sectional view illustrating the positional relationship between a sealing portion of the photoelectric conversion element and the surface of an anchoring layer;

FIGS. 3A to 3C are process diagrams illustrating examples of manufacturing steps of the photoelectric conversion element module according to the first embodiment of the present technology;

FIG. 4A is a cross-sectional view illustrating a first modification example of the photoelectric conversion element module according to the first embodiment of the present technology, FIG. 4B is a cross-sectional view illustrating a second modification example of the photoelectric conversion element module according to the first embodiment of the present technology, and FIG. 4C is a cross-sectional view illustrating a third modification example of the photoelectric conversion element module according to the first embodiment of the present technology;

FIG. 5A is a plan view illustrating a configuration example of a photoelectric conversion element module according to a second embodiment of the present technology, and FIG. 5B is a cross-sectional view along line VB-VB in FIG. 5A;

FIG. 6 is a cross-sectional view illustrating a modification example of the photoelectric conversion element module according to the second embodiment of the present technology;

FIG. 7A is a cross-sectional view illustrating a first configuration example of a photoelectric conversion element module according to a third embodiment of the present technology, FIG. 7B is a cross-sectional view illustrating a second configuration example of the photoelectric conversion element module according to the third embodiment of the present technology, and FIG. 7C is a cross-sectional view illustrating a third configuration example of the photoelectric conversion element module according to the third embodiment of the present technology;

FIG. 8 is a cross-sectional view illustrating a configuration example of a photoelectric conversion element module according to a fourth embodiment of the present technology;

FIG. 9 is a cross-sectional view illustrating a configuration example of a photoelectric conversion element module according to a fifth embodiment of the present technology;

FIG. 10 is a cross-sectional view illustrating a configuration example of a photoelectric conversion element module according to a sixth embodiment of the present technology; and

FIG. 11 is a cross-sectional view illustrating a configuration example of a photoelectric conversion element module according to a seventh embodiment of the present technology.

### DETAILED DESCRIPTION OF THE PREFERRED EMBODIMENTS

A description will be given below of the preferred embodiments of the present technology in the following order:

1. First Embodiment (example in which the rear sides of a plurality of photoelectric conversion elements are anchored with an anchoring layer)
2. Second Embodiment (example in which the incident sides of a plurality of photoelectric conversion elements are supported with a support)
3. Third Embodiment (example in which a housing body has a variety of functions)
4. Fourth Embodiment (example in which the incident side of each of the photoelectric conversion elements is in close contact with the housing body)
5. Fifth Embodiment (example in which the surroundings of the plurality of photoelectric conversion elements are anchored with spacers)
6. Sixth Embodiment (example in which the plurality of photoelectric conversion elements are anchored inside the housing body with an energy ray-setting adhesive)
7. Seventh Embodiment (example in which both of the main sides of a plurality of photoelectric conversion elements are supported with supports)

### 1. First Embodiment

### Configuration of the Photoelectric Conversion Element Module

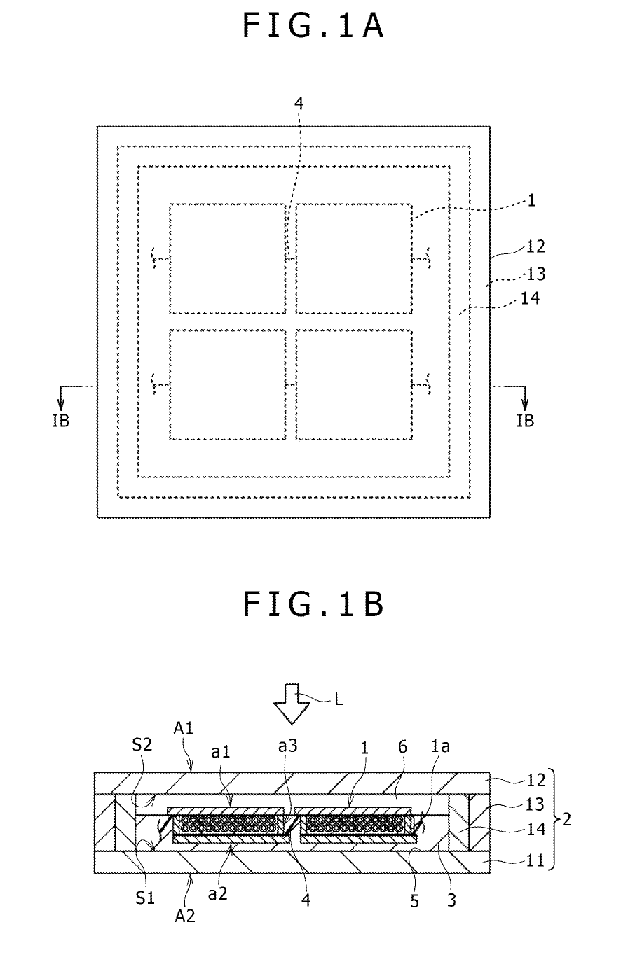

FIG. 1A is a plan view illustrating a configuration example of a photoelectric conversion element module according to a first embodiment of the present technology. FIG. 1B is a cross-sectional view along line IB-IB in FIG. 1A. As illustrated in FIGS. 1A and 1B, this photoelectric conversion element module includes a plurality of photoelectric conversion elements 1, a housing body 2 adapted to house the plurality of photoelectric conversion elements 1 and an anchoring layer 3 adapted to anchor the positions of the photoelectric conversion elements 1 inside the housing body 2. This photoelectric conversion element module is a so-called dye sensitized photoelectric conversion element module adapted to convert incident light L such as sunlight into electric energy and supply this energy to external equipment as electric power. The photoelectric conversion element module has two sides, an incident side A1 on which the incident light L such as sunlight falls, and a rear side A2 opposite to the incident side A1.

The housing body 2 has a housing space 5 in which to house the plurality of photoelectric conversion elements 1. The housing body 2 has a first inner side S1 and a second inner side S2 opposed to the first inner side S1. The anchoring layer 3 is provided on the first inner side S1. The housing space 5 is formed by the first inner side S1 and second inner side S2. A hollow layer 6 is formed between the anchoring layer 3 and second inner side S2. Each of the plurality of photoelectric conversion elements 1 has an incident side a1, rear side a2 and lateral side a3. The incident light L such as sunlight falls on the incident side a1. The rear side a2 is opposite to the incident side a1. The lateral side a3 is provided between the incident side a1 and rear side a2. The rear side a2 of the photoelectric conversion element 1 is arranged to be opposed to the first inner side S1 of the housing body 2 and anchored by the anchoring layer 3. On the other hand, the incident side a1 of the photoelectric conversion element 1 is arranged to be opposed to the second inner side S2 of the housing body 2 and left open to the hollow layer 6. That is, the rear side a2 of the photoelectric conversion element 1 is buried in the anchoring layer 3 so that the incident side a1 of the photoelectric conversion element 1 and the second inner side S2 of the housing body 2 are spaced from each other and so that the hollow layer 6 is formed therebetween. The anchoring layer 3 should preferably cover the photoelectric conversion element 1 from the rear side a2 to a sealing portion 1a.

The plurality of photoelectric conversion elements 1 are electrically connected together in series and/or in parallel by a plurality of wirings (connection members) 4, thus supplying electric power generated by each of the plurality of photoelectric conversion elements 1 to equipment external to the photoelectric conversion element module via the plurality of wirings 4. Although an example is shown in FIGS. 1A and 1B in which the four photoelectric conversion elements 1 are housed in the housing body 2, the number of the photoelectric conversion elements 1 is not limited to this example.

### (Housing Body)

The housing body 2 should preferably be hermetically sealed from the viewpoint of suppressing the entry of outside moisture. The housing body 2 includes, for example, first and second base materials 11 and 12 and a sealant 13. The housing body 2 may further include a shielding material 14 as necessary.

The first base material 11 has the first inner side

S1 opposed to the second base material 12, and the second base material 12 has the second inner side S2 opposed to the first base material 11. The first and second base materials 11 and 12 are arranged to be opposed to each other in such a manner that the first and second inner sides S1 and S2 are spaced from each other, with the sealant 13 provided between the peripheral portions of the first and second inner sides S1 and S2. The housing space 5 adapted to house the plurality of photoelectric conversion elements 1 is formed by the first and second base materials 11 and 12 and sealant 13. The photoelectric conversion element module has the plurality of photoelectric conversion elements 1 between the first and second base materials 11 and 12. Each of the photoelectric conversion elements 1 is anchored to the first base material 11 via the anchoring layer 3. The anchoring layer 3 covers the photoelectric conversion element 1 up to the sealing portion 1a. Each of the photoelectric conversion elements 1 has the incident side a1 and the rear side a2 opposed to the incident side a1, with the anchoring layer 3 anchoring the rear side a2 of the photoelectric conversion element 1. The hollow layer 6 is formed between the photoelectric conversion element 1 and second base material 12.

### (Second Base Material)

A material that can be used as the second base material 12 is not specifically limited so long as it is transparent, and a variety of materials can be used as the second base material 12. For example, a transparent inorganic or plastic base material can be used. Of all these materials, a transparent plastic material is preferred in consideration of workability and lightweight. As for the shape of the second base material 12, a transparent film, sheet, substrate and so on can be used. A material having not only excellent capability to shut off outside moisture and gases which would otherwise find their way into the photoelectric conversion element 1 but also excellent solvent resistance, weather resistance and other characteristics is preferred. Among inorganic materials having such characteristics are quartz, sapphire and glass. Among plastic materials having such characteristics are well-known polymer materials. More specifically, among well-known polymer materials are triacetyl cellulose (TAC), polyester (TPEE), polyethylene terephthalate (PET), polyethylene naphthalate (PEN), polyimide (PI), polyamide (PA), aramid, polyethylene (PE), polyacrylate, polyether sulfone, polysulfone, polypropylene (PP), diacetyl cellulose, polyvinyl chloride, acrylic resin (PMMA), polycarbonate (PC), epoxy resin, urea resin, urethane resin, melamine resin and cycloolefin polymer (COP). Of all these inorganic and plastic materials, that having high transmittance in the visible region is particularly preferred. However, a material that can be used as the second base material 12 is not limited thereto. If the photoelectric conversion element module is used as a construction member such as window material, the second base material 12 should preferably be made of a glass plate.

### (First Base Material)

A material that can be used as the first base material 11 is not specifically limited to being transparent. Instead, an opaque material can also be used. For example, a variety of base materials including opaque or transparent inorganic or plastic base materials can be used. As for the shape of the first base material 11, a film, sheet, substrate and so on can be used. Although any of the materials given above as examples for the second base material 12 may be similarly used as an inorganic or plastic base material, opaque base materials such as metallic ones may also be used in addition to the above. If the photoelectric conversion element module is used as a construction member such as window material, the first base material 11 should preferably be made of a glass plate.

### (Anchoring Layer)

The anchoring layer 3 contains a set adhesive as a main ingredient. The adhesive contains one or more adhesives selected, for example, from a group of thermoplastic, thermosetting, room-temperature-setting and energy ray-setting adhesives as main ingredients. The adhesive should preferably contain at least one of a room-temperature-setting and energy ray-setting adhesive as a main ingredient from the viewpoint of suppressing the reduction in performance of the photoelectric conversion element 1 due to heat. The anchoring layer 3 may further contain, as necessary, a hardener, catalyst, accelerant, solvent, diluent, plasticizer, tackifier, filler, age resistor or adhesion promoter. The anchoring layer 3 may still further contain, as necessary, fine particles. Both organic and inorganic fine particles may be, for example, used as fine particles.

As a thermoplastic adhesive, for example, vinyl acetate-based adhesive, polyvinyl alcohol-based adhesive, polyvinyl acetal-based adhesive, vinyl chloride-based adhesive, acrylic adhesive, polyethylene-based adhesive and cellulose-based adhesive may be used alone or two or more thereof may be mixed. More specifically, ethylene vinyl acetate (EVA) and polyvinyl butyral (PVB) are preferred for use. A hot-melt adhesive may also be used as a thermoplastic adhesive.

As a thermosetting adhesive, for example, urea-based adhesive, resorcinol-based adhesive, melamine-based adhesive, phenol-based adhesive, epoxy-based adhesive, polyurethane-based adhesive, polyester-based adhesive, polyimide-based adhesive and polyaromatic-based adhesive may be used alone or two or more thereof may be mixed.

As a room-temperature-setting adhesive, for example, not only two-liquid reaction epoxy-based adhesive, acrylic adhesive and polyester-based adhesive but also liquid glass may also be used. Liquid glass contains silicon dioxide silica solution as a main ingredient and sets and changes into a solid, i.e., amorphous glass, when left exposed to air at room temperature.

Energy ray-setting adhesive is a resin composition which sets when irradiated with an energy ray. Here, the term “energy ray” refers to that which can trigger the polymerization reaction involving radicals, cations and anions such as electron ray, ultraviolet ray, infrared ray, laser beam, visible light, nonionizing radiation (e.g., X-, α, β and γ rays), microwave and radio frequency. Further, energy ray-setting resin composition may be an organic/inorganic hybrid material. Still further, two or more different energy ray-setting resin compositions may be mixed for use. An ultraviolet-setting adhesive which sets with ultraviolet ray is preferred for use as an energy ray-setting adhesive.

The rear side a2 of the photoelectric conversion element 1 should preferably be spaced from the first inner side S1 of the first base material 11, with the anchoring layer 3 lying therebetween. In this case, the elastic modulus of the anchoring layer 3 should preferably be 500 MPa or less, and more preferably from 100 to 10 MPa. An elastic modulus of 500 MPa or less allows for the anchoring layer 3 to accommodate, if any the difference in thermal expansion coefficient between the material making up the rear side a2 of the photoelectric conversion element 1 and that making up the first inner side S1 of the housing body 2, thus providing reduced module stress. Further, even if the housing body 2 deforms due, for example, to rainfall or wind pressure when the photoelectric conversion element module is used as a construction member such as window material, the anchoring layer 3 acts as an elastic absorber, remaining flexible under external stress and contributing to reduced stress on the photoelectric conversion element 1.

Here, the elastic modulus was measured at a temperature of 25° C. More specifically, the elastic modulus was measured by tensile or compression test using a differential transformer extensometer. The elastic modulus can be derived from the relation E=σ/ε in the elastic deformation range where E[MPa] is the elastic modulus, σ[MPa] the stress, and ε[%] the distortion.

### (Sealant)

The sealant 13 is provided, for example, between the peripheral portions of the first inner side S1 of the first base material 11 and the second inner side S2 of the second base material 12. The sealant 13 contains, for example, an adhesive or agglutinant as a main ingredient. If an adhesive is used, the sealant 13 contains one or more adhesives selected, for example, from a group of thermoplastic, thermosetting, room-temperature-setting and energy ray-setting adhesives as main ingredients and may further contain, as necessary, an additive. If an adhesive is used, polysulfide is preferred from the viewpoint of bonding strength. If an agglutinant is used, the sealant 13 contains one or more agglutinants selected, for example, from a group of acrylic, rubber-based and silicon-based agglutinants as main ingredients and may further contain, as necessary, an additive such as crosslinking agent.

### (Shielding Material)

The shielding material 14 is provided, for example, between the peripheral portions of the first inner side S1 of the first base material 11 and the second inner side S2 of the second base material 12. The shielding material 14 is provided on the inner side of the sealant 13 (on the side of the housing space 5) in such a manner as to be adjacent to or spaced from the sealant 13. A material capable of preventing or suppressing the leakage of the material housed in the housing space 5 and/or the entry of moisture such as steam from the outside environment into the housing space 5 is preferred for use as the shielding material 14. As such a material, shielding materials offering low steam permeability such as polyolefin and polyisobutylene and metallic spacer incorporating a dry material may be used alone or in combination.

### (Hollow Layer)

The hollow layer 6 should preferably be in a dry air, inert gas or vacuum atmosphere because this can suppress the characteristic degradation of the photoelectric conversion element 1. Among inert gases are Ar (argon) and Kr (krypton) gases.

### (Photoelectric Conversion Element)

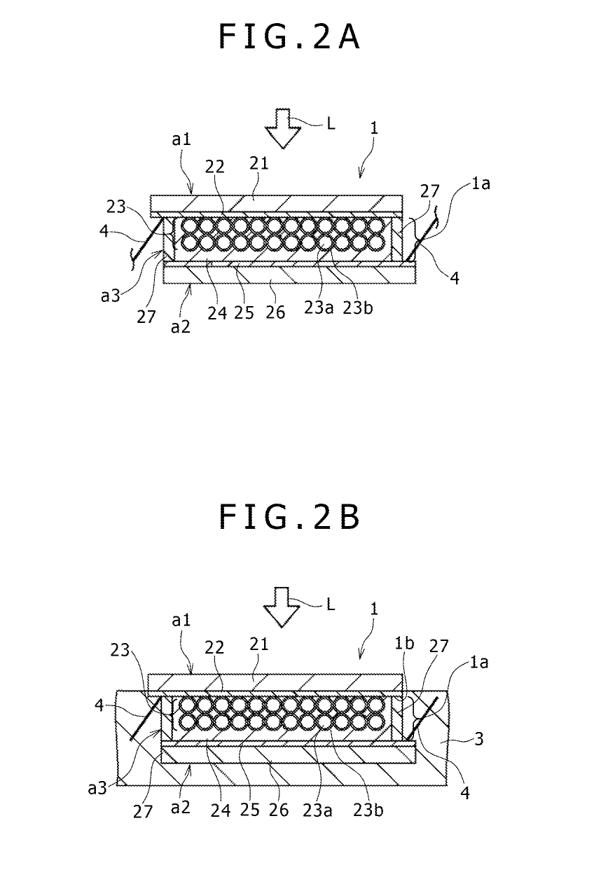

FIG. 2A is a cross-sectional view illustrating a configuration example of the photoelectric conversion element. The photoelectric conversion element 1 is a so-called dye sensitized photoelectric conversion element which includes a transparent base material 21, transparent electrode 22, porous semiconductor layer 23, electrolyte layer 24, opposed electrode 25, opposed base material 26 and a sealant 27 as illustrated in FIG. 2A. Here, the transparent electrode 22, porous semiconductor layer 23, electrolyte layer 24 and opposed electrode 25 form a power generating element section. This power generating element section is provided between the transparent base material 21 and opposed base material 26.

The opposed base material 26 is provided to be opposed to the transparent base material 21. The transparent base material 21 has a main side opposed to the opposed base material 26. The transparent electrode 22 is formed on this main side, and the porous semiconductor layer 23 is formed on the surface of the transparent electrode 22. The opposed base material 26 has a main side opposed to the transparent base material 21. The opposed electrode 25 is formed on this main side. The electrolyte layer 24 lies between the porous semiconductor layer 23 and opposed electrode 25 that are arranged to be opposed to each other.

The sealant 27 is provided on the peripheral portions of the opposed sides of the transparent base material 21 and opposed base material 26. The clearance between the porous semiconductor layer 23 and opposed electrode 25 should preferably be 1 to 100 μm, and more preferably 1 to 40 μm. The electrolyte layer 24 is sealed in a space surrounded by three components, firstly, the transparent base material 21 on which the transparent electrode 22 and porous semiconductor layer 23 are formed, secondly, the opposed base material 26 on which the opposed electrode 25 is formed, and thirdly, the sealant 27.

### (Transparent Base Material)

A material that can be used as the transparent base material 21 is not specifically limited so long as it is transparent, and a variety of base materials can be used as the transparent base material 21. For example, a transparent inorganic or plastic base material can be used. Of all these materials, a transparent plastic base material is preferred in consideration of workability and lightweight. As for the shape of the base material, a transparent film, sheet, substrate and so on can be used. A material having not only excellent capability to shut off outside moisture and gases which would otherwise find their way into the photoelectric conversion element 1 but also excellent solvent resistance, weather resistance and other characteristics is preferred. Among inorganic base materials having such characteristics are quartz, sapphire and glass. Among plastic base materials having such characteristics are well-known polymer materials. More specifically, among well-known polymer materials are triacetyl cellulose (TAC), polyester (TPEE), polyethylene terephthalate (PET), polyethylene naphthalate (PEN), polyimide (PI), polyamide (PA), aramid, polyethylene (PE), polyacrylate, polyether sulfone, polysulfone, polypropylene (PP), diacetyl cellulose, polyvinyl chloride, acrylic resin (PMMA), polycarbonate (PC), epoxy resin, urea resin, urethane resin, melamine resin and cycloolefin polymer (COP). Of all these inorganic and plastic base materials, that having high transmittance in the visible region is particularly preferred. However, a material that can be used as the transparent base material 21 is not limited thereto.

### (Opposed Base Material)

A material that can be used as the opposed base material 26 is not specifically limited to being transparent. Instead, an opaque material can also be used. For example, a variety of base materials including opaque or transparent inorganic or plastic base materials can be used. Although any of the materials given above as examples for the transparent base material 21 may be similarly used as an inorganic or plastic base material, opaque base materials such as metallic ones may also be used in addition to the above.

### (Sealant)

Thermoplastic and photo-setting resins and glass frit can be, for example, used as the sealant 27. However, a material that can be used as the sealant 27 is not limited thereto.

### (Transparent Electrode)

The transparent electrode 22 should preferably offer low light absorption in the visible to near infrared regions of sunlight. A transparent conductive material can be used as the transparent electrode 22. A metal oxide having excellent conductivity or carbon, for example, is preferred for use as a transparent conductive material. For example, one or more selected, for example, from a group of indium-tin composite oxide (ITO), fluorine-doped SnO₂ (FTC)), antimony-doped SnO₂ (ATO), tin oxide (SnO₂), zinc oxide (ZnO), indium-zinc composite oxide (IZO), aluminum-zinc composite oxide (AZO) and gallium-zinc composite oxide (GZO) can be used as a metal oxide. A layer intended to promote binding, provide improved electron transfer or prevent reverse electron process may be further provided between the transparent electrode 22 and porous semiconductor layer 23.

### (Porous Semiconductor Layer)

The porous semiconductor layer 23 should preferably be a porous layer including metal oxide semiconductor fine particles 23a. The metal oxide semiconductor fine particles 23a should preferably hold a sensitizing dye 23b on their surface. The metal oxide semiconductor fine particles 23a should preferably include a metal oxide containing at least one of titanium, zinc, tin and niobium. More specifically, one or more selected from a group of titanium oxide, tin oxide, tungsten oxide, zinc oxide, indium oxide, niobium oxide, iron oxide, nickel oxide, cobalt oxide, strontium oxide, tantalum oxide, antimony oxide, lanthanoid oxide, yttrium oxide, vanadium oxide and so on can be used as the metal oxide semiconductor fine particles 23a. However, a material that can be used as the metal oxide semiconductor fine particles 23a is not limited thereto. In order for the surface of the porous semiconductor layer 23 to be sensitized by the sensitizing dye 23b, the conduction band of the porous semiconductor layer 23 should be located where electrons can be readily gained from the photoexcitation level of the sensitizing dye 23b. From this point of view, it is particularly preferred to select one or more from a group of titanium oxide, zinc oxide, tin oxide and niobium oxide of all the materials given above for use as the metal oxide semiconductor fine particles 23a. Further, titanium oxide is most preferred from the viewpoint of price and environmental hygiene. It is particularly preferred that the metal oxide semiconductor fine particles 23a should contain titanium oxide having an anatase or brookite crystal structure. The mean primary particle diameter of the metal oxide semiconductor fine particles 23a should preferably be 5 nm or more and 500 nm or less. A mean primary particle diameter smaller than 5 nm tends to lead to degraded crystallinity, making it difficult to maintain an anatase structure and resulting in an amorphous structure. On the other hand, a mean primary particle diameter greater than 500 nm tends to lead to reduced specific surface area, resulting in a reduced total amount of the sensitizing dye 23b adsorbed to the porous semiconductor layer 23 for contribution to power generation.

### (Sensitizing Dye)

A material that can be used as the sensitizing dye 23b for photoelectric conversion is not specifically limited so long as it has sensitizing effect. However, a substance capable of absorbing light in and near the visible region is commonly used such as bipyridine complex, terpyridine complex, merocyanine dye, porphyrin or phthalocyanine.

As the sensitizing dye 23b to be used alone, cis-bis (isothiocyanato) bis(2,2′-bipyridyl-4,4′-dicarboxylic acid)-ruthenium (II) bis-tetrabutylammonium complex, i.e., a kind of bipyridine complex (commonly known as N719), is generally used for its excellent performance. In addition to the above, cis-bis(isothiocyanato) bis(2,2′-bipyridyl-4,4′-dicarboxylic acid)-ruthenium (II), i.e., a kind of bipyridine complex (commonly known as N3), and tris (isothiocyanato)(2,2′:6′,2″-terpyridyl-4,4′,4″-tricarboxylic acid)-ruthenium (II) tris-tetrabutylammonium complex, i.e., a kind of terpyridine complex (commonly known as black dye) are generally used.

In particular, when the N3or black dye is used, a coadsorbent is also often used. A coadsorbent is a molecule added to prevent the association of dye molecules on the porous semiconductor layer 23. Among typical coadsorbents are chenodeoxycholic acid, taurodeoxycholic acid and 1-decryl phosphonic acid. These molecules offer such structural characteristics as having a carboxyl or phosphono group as a functional group readily adsorbed to titanium oxide making up the porous semiconductor layer 23 and being formed by σ bond so as to lie between the dye molecules and prevent the interference therebetween.

Among other dyes for use as the sensitizing dye 23b are azo-based dyes, quinacridone-based dyes, diketopyrrolopyrrole-based dyes, squarylium-based dyes, cyanine-based dyes, merocyanine-based dyes, triphenylmethane-based dyes, xanthene-based dyes, porphine-based dyes, chlorophyll-based dyes, ruthenium complex-based dyes, indigo-based dyes, perylene-based dyes, oxazine-based dyes, anthraquinone-based dyes, phthalocyanine-based dyes and naphthalocyanine-based dyes and their derivatives. However, the dye for use as the sensitizing dye 23b is not limited thereto so long as it is capable of absorbing light and injecting excited electrons into the conduction band of the porous semiconductor layer 23. It is preferred that these dyes for use as the sensitizing dye 23b should have one or more linkage groups in their structure because if so, the dyes can be linked to the surface of the porous semiconductor layer, thus making it possible to speedily transfer excited electrons of the photo-excited sensitizing dye 23b to the conduction band of the porous semiconductor layer 23.

The thickness of the porous semiconductor layer 23 should preferably be 0.5 μm or more and 200 μm or less. A thickness smaller than 0.5 μm tends to lead to failure to provide an effective conversion efficiency. On the other hand, a thickness greater than 200 μm tends to lead to difficulties in manufacture, such as cracking and peeling during the formation. Further, a thickness greater than 200 μm leads to a greater distance between the surface of the porous semiconductor layer 23 on the side of the electrolyte layer and that of the transparent electrode 22 on the side of the porous semiconductor layer. As a result, it becomes difficult to effectively transfer generated electric charge to the transparent electrode 22, thus resulting in reduced tendency to achieve excellent conversion efficiency.

### (Opposed Electrode)

The opposed electrode 25 serves as a cathode of the photoelectric conversion element 1. Among conductive materials for use as the opposed electrode 25 are metals, metal oxides and carbon. However, a material that can be used as the opposed electrode 25 is not limited thereto. Among metals that can be used as the opposed electrode 25 are platinum, gold, silver, copper, aluminum, rhodium and indium. However, the metal for use as the opposed electrode 25 is not limited thereto. Among metal oxides that can be used as the opposed electrode 25 are ITO (indium-tin oxide), tin oxide (including, for example, fluorine-doped tin oxides) and zinc oxide. However, the metal oxide for use as the opposed electrode 25 is not limited thereto. Although not specifically limited, the thickness of the opposed electrode 25 should preferably be 5 nm or more and 100 μm or less.

### (Electrolyte Layer)

The electrolyte layer 24 should preferably be made of an electrolyte, medium and additive. Among electrolytes that can be used are a mixture of I₂ and iodide (e.g., LiI, NaI, KI, CsI, MgI₂, CaI₂, CuI, tetraalkyl ammonium iodide, pyridinium iodide and imidazolium iodide) and a mixture of Br₂ and bromide (e.g., LiBr). Of these, the electrolytes obtained by mixing I₂ and iodide such as LiI, pyridinium iodide and imidazolium iodide are preferred. However, the combination thereof is not limited to the above.

The concentration of the electrolyte in the medium should preferably be 0.05 to 10 M, and more preferably 0.05 to 5 M, and even more preferably 0.2 to 3 M. The concentration of I₂ and Br₂ should preferably be 0.0005 to 1 M, and more preferably 0.001 to 0.5 M, and even more preferably 0.001 to 0.3 M. On the other hand, a variety of additives such as 4-tert-butylpyridine and benzimidazoliums may be added to provide improved open circuit voltage of the photoelectric conversion element 1.

The medium used as the electrolyte layer 24 should preferably be a compound that can provide excellent ionic conductivity. Among media in a liquid form that can be used as the electrolyte layer 24 are ether compounds such as dioxane and diethyl ether, chain ethers such as ethylene glycol dialkyl ether, propylene glycol dialkyl ether, polyethylene glycol dialkyl ether and polypropylene glycol dialkyl ether, alcohols such as methanol, ethanol, ethylene glycol monoalkyl ether, propylene glycol monoalkyl ether, polyethylene glycol monoalkyl ether and polypropylene glycol monoalkyl ether, polyvalent alcohols such as ethylene glycol, propylene glycol, polyethylene glycol, polypropylene glycol and glycerin, nitrile compounds such as acetonitrile, glutarodinitrile, methoxyacetonitrile, propionitrile and benzonitrile, carbonate compounds such as ethylene carbonate and propylene carbonate, heterocyclic compounds such as 3-methyl-2-oxazolidinone, and aprotic polar substances such as dimethyl sulfoxide and sulfolane.

Further, the electrolyte layer 24 may contain a polymer to use a medium in a solid form (including gel form). In this case, a polymer such as polyacrylonitrile or polyvinylidene fluoride is added to the medium in a solution form, thus polymerizing a multi-functional monomer having an ethylene unsaturated group in the medium in a solution form, and transforming the medium into a solid form.

In addition to the above, electrolytes for which CuI or CuSCN medium is not necessary and hole transporting materials such as 2,2′,7,7′-tetrakis (N,N-di-p-methoxyphenylamine) 9,9′-spirobifluorene may be used as the electrolyte layer 24.

(Positional Relationship between the Photoelectric Conversion Element and Anchoring Layer)

FIG. 2B is a cross-sectional view illustrating the positional relationship between the sealing portion of the photoelectric conversion element and the surface of an anchoring layer. The photoelectric conversion element 1 has the sealing portion 1a on the lateral side a3 of the peripheral portion of the photoelectric conversion element 1. More specifically, a gap portion 1b is formed between the peripheral portions of the transparent base material 21 and opposed base material 26. The gap portion 1b is filled with the sealant 27, thus forming the sealing portion 1a. The rear side a2 of the photoelectric conversion element 1 is buried in the anchoring layer 3. As a result, the sealing portion 1a provided on the peripheral portion of the lateral side a3 is covered with the anchoring layer 3. The anchoring layer 3 should preferably cover at least part of the sealing portion 1a, and more preferably all of the sealing portion 1a. In contrast, the incident side a1 of the photoelectric conversion element 1 is exposed to the hollow layer 6 without being covered with the anchoring layer 3.

### [Manufacturing Method of the Photoelectric Conversion Element Module]

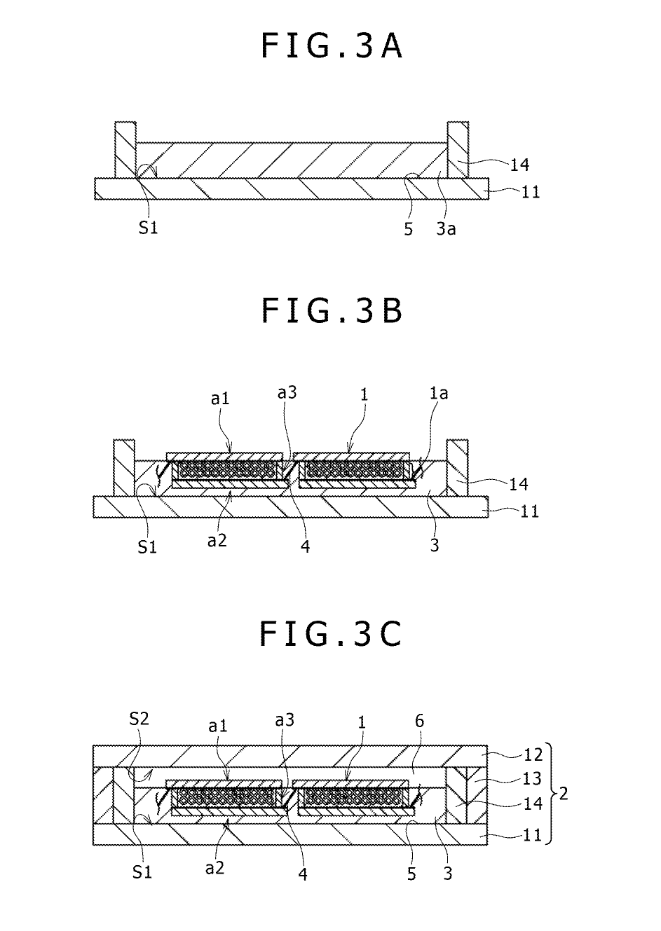

FIGS. 3A to 3C are process diagrams illustrating examples of manufacturing methods of the photoelectric conversion element module according to the first embodiment of the present technology.

First, as illustrated in FIG. 3A, the shielding material 14 is formed on the peripheral portion of the first inner side S1 of the first base material 11. Then, an adhesive layer 3a in a liquid or molten form is formed in a space surrounded by the shielding material 14. This adhesive layer 3a contains the above adhesive as a main ingredient.

Next, as illustrated in FIG. 3B, the rear sides a2 of the plurality of photoelectric conversion elements 1 are caused to sink into the adhesive layer 3a. At this time, the sealing portion 1a provided on the lateral side a3 of each of the photoelectric conversion elements 1 is covered with the adhesive. Next, for example, the adhesive layer 3a in a liquid or molten form is set by cooling, by heating, at room temperature or by energy ray, thus forming the anchoring layer 3 on the first inner side S1 of the first base material 11. This allows for the plurality of photoelectric conversion elements 1 to be anchored to the first inner side S1 of the first base material 11.

If a thermoplastic or thermosetting adhesive is used as an adhesive, it is preferred to minimize the impact of pressure and heat applied to the photoelectric conversion element 1. More specifically, if a thermoplastic adhesive is used as an adhesive, for example, it is preferred that when the resin cross-linking ratio increases as a result of softening and liquefaction of the thermoplastic adhesive, the photoelectric conversion element 1 should be placed on the thermoplastic adhesive for bonding. The reason for this is that continuous heating stress can be reduced. From the viewpoint of reducing the impact of heating on the photoelectric conversion element 1, it is preferred to cool the incident side a1, i.e., the side opposite to the bonded side (rear side a2), of the photoelectric conversion element 1. Further, a small pressure may be applied to the incident side a1, i.e., the side opposite to the bonded side (rear side a2), of the photoelectric conversion element 1 as necessary. This allows for firmer bonding of the photoelectric conversion element 1.

If a room-temperature-setting adhesive is used, it is possible to keep thermal stress on the photoelectric conversion element 1 to an insignificant level because the temperature rise that could take place during setting is a maximum of about 80° C. If an ultraviolet-setting adhesive is used, it is possible to bond the photoelectric conversion element 1 without causing performance degradation of the photoelectric conversion element 1 by bonding the rear side a2, i.e., the side not contributing to power generation, of the photoelectric conversion element 1 by ultraviolet radiation. If the incident side a1, i.e., the side contributing to power generation, of the photoelectric conversion element 1 is bonded to the housing body 2, it is preferred to apply the ultraviolet-setting adhesive only to the peripheral portion of the incident side a1 of the photoelectric conversion element 1 and radiate ultraviolet rays only onto this peripheral portion. Among methods used to radiate ultraviolet rays only onto this peripheral portion are using a light-shielding mask and radiating ultraviolet rays in a linear manner.

Next, as illustrated in FIG. 3C, the first base material 11, to which the photoelectric conversion elements 1 are anchored, and the second base material 12 are arranged to be opposed to each other in such a manner that the first and second inner sides S1 and S2 are opposed to each other. At the same time, the first and second base materials 11 and 12 are attached together via the sealant 13 provided on the peripheral portions thereof.

### [Operation of the Photoelectric Conversion Element Module]

A description will be given next of the operation of the photoelectric conversion element module according to the first embodiment of the present technology.

The photoelectric conversion element 1 operates as a cell with the opposed electrode 25 serving as a cathode and the transparent electrode 22 serving as a anode when the light L enters the incident side a1 of the first base material 11. The operating principle thereof is as described below.

When the photons that have passed through the transparent base material 21 and transparent electrode 22 are absorbed by the sensitizing dye 23b, the electrons in the sensitizing dye 23b are excited from a ground state (HOMO) to an excited state (LUMO). The electrons in an excited state are promoted into the conduction band of the porous semiconductor layer 23 via electrical coupling between the sensitizing dye 23b and porous semiconductor layer 23, reaching the transparent electrode 22 through the porous semiconductor layer 23.

On the other hand, the sensitizing dye 23b that has lost its electrons gains electrons from a reducing agent such as I⁻ in the electrolyte layer 24, for example, as a result of the reaction shown below, producing an oxidizing agent such as I₃⁻ (conjugate between I₂ and I⁻) in the electrolyte layer 24.

2I⁻→I₂+2e⁻

I₂+I⁻→I₃⁻

The produced oxidizing agent such as I₃⁻ reaches the opposed electrode 25 by diffusion, gaining electrons from the opposed electrode 25, for example, as a result of the reaction shown below (opposite reaction of that described above), and being reduced to the original reducing agent such as I⁻.

I₃⁻→I₂+I⁻

I₂+2e⁻→2I⁻

The electrons transferred from the transparent electrode 22 to an external circuit perform electrical work in the external circuit and then return to the opposed electrode 25. Thus, optical energy is converted into electrical energy without making any change to the sensitizing dye 23b or electrolyte layer 24.

### First Modification Example

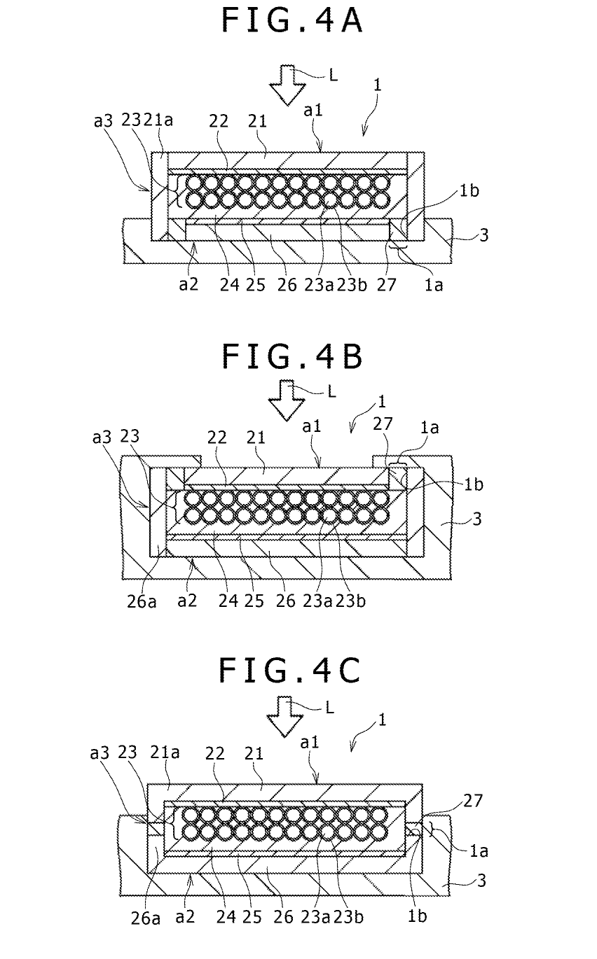

FIG. 4A is a cross-sectional view illustrating a first modification example of the photoelectric conversion element module according to the first embodiment of the present technology. The photoelectric conversion element 1 has the sealing portion 1a on the rear side a2 of the peripheral portion of the photoelectric conversion element 1. More specifically, a side wall portion 21a projecting toward the opposed base material 26 is provided on the peripheral portion of the transparent base material 21. Further, the opposed base material 26 is arranged on the inside of the tip portion of the side wall portion 21a, and the gap portion 1b is formed between the tip portion of the side wall portion 21a and the edge portion of the opposed base material 26. The gap portion 1b is filled with the sealant 27, thus forming the sealing portion 1a. The same materials as those for the transparent base material 21 can be used as the side wall portion 21a. The side wall portion 21a and transparent base material 21 are molded separately from or integrally with each other. From the viewpoint of productivity, they should preferably be molded integrally.

The rear side a2 of the photoelectric conversion element 1 is buried in the anchoring layer 3, and the sealing portion 1a provided on the peripheral portion of the rear side a2 is covered with the anchoring layer 3. In contrast, the incident side a1 of the photoelectric conversion element 1 is exposed to the hollow layer 6 without being covered with the anchoring layer 3.

### Second Modification Example

FIG. 4B is a cross-sectional view illustrating a second modification example of the photoelectric conversion element module according to the first embodiment of the present technology. More specifically, a side wall portion 26a projecting toward the transparent base material 21 is provided on the peripheral portion of the opposed base material 26. Further, the transparent base material 21 is arranged on the inside of the tip portion of the side wall portion 26a, and the gap portion 1b is formed between the tip portion of the side wall portion 26a and the edge portion of the transparent base material 21. The gap portion 1b is filled with the sealant 27, thus forming the sealing portion 1a. The same materials as those for the opposed base material 26 can be used as the side wall portion 26a. The side wall portion 26a and opposed base material 26 are molded separately from or integrally with each other. From the viewpoint of productivity, they should preferably be molded integrally.

The photoelectric conversion element 1 has the sealing portion 1a on the incident side a1 of the peripheral portion of the photoelectric conversion element 1. The photoelectric conversion element 1 is buried in the anchoring layer 3 from the rear side a2 thereof to the peripheral portion of the incident side a1 thereof, and the sealing portion 1a provided on the peripheral portion of the incident side a1 is covered with the anchoring layer 3. In contrast, the portions other than the peripheral portion of the incident side a1 of the photoelectric conversion element 1, i.e., the portion contributing to photoelectric conversion, are exposed to the hollow layer 6 without being covered with the anchoring layer 3.

### Third Modification Example

FIG. 4C is a cross-sectional view illustrating a third modification example of the photoelectric conversion element module according to the first embodiment of the present technology. The photoelectric conversion element 1 has the sealing portion 1a on the lateral side a3 of the peripheral portion of the photoelectric conversion element 1. More specifically, the side wall portion 21a projecting toward the opposed base material 26 is provided on the peripheral portion of the transparent base material 21. The side wall portion 26a projecting toward the transparent base material 21 is provided on the peripheral portion of the opposed base material 26. Further, the gap portion 1b is formed between the tip portions of the side wall portions 21a and 26a. The gap portion 1b is filled with the sealant 27, thus forming the sealing portion 1a.

The photoelectric conversion element 1 is buried in the anchoring layer 3 from the rear side a2 thereof to the sealing portion 1a of the lateral side a3 thereof, and the sealing portion 1a provided on the lateral side a3 is covered with the anchoring layer 3. In contrast, the incident side a1 of the photoelectric conversion element 1 is exposed to the hollow layer 6 without being covered with the anchoring layer 3.

### (Effect)

In the first embodiment, the photoelectric conversion element 1 is covered with the anchoring layer 3 from the rear side a2 to the sealing portion 1a, thus making it possible to reinforce the sealing portion 1a. Further, it is possible to suppress the entry of moisture from the sealing portion 1a into the photoelectric conversion element 1, thus providing improved weather resistance to the photoelectric conversion element module. This makes it possible to achieve a photoelectric conversion element module that can meet the weather resistant reliability levels for use, for example, outside buildings and ordinary homes.

Further, the sealing portion 1a is provided on the peripheral portion of the photoelectric conversion element 1. In addition, the photoelectric conversion element 1 is covered with the anchoring layer 3 from the rear side a2 to the sealing portion 1a. This ensures that the area of the incident side a1 of the photoelectric conversion element 1 contributing to power generation is exposed. Therefore, it is possible to suppress the reduction in amount of light reaching the area of the incident side a1 of the photoelectric conversion element 1 contributing to power generation. That is, it is possible to provide improved light utilization efficiency to the photoelectric conversion element module.

Still further, the hollow layer 6 is provided between the incident side a1 of the photoelectric conversion element 1 and the second inner side S2 of the second base material 12. This provides secondary functions such as thermal insulation and soundproofing to the photoelectric conversion element module. If the first and second base materials 11 and 12 of the housing body 2 are made of glass plates, the photoelectric conversion element module can be used as eco-friendly glass such as multi-layer glass.

Still further, the incident side a1 of the photoelectric conversion element 1 is exposed without being covered with the anchoring layer 3. Therefore, an opaque material can be used as the anchoring layer 3. This provides a wider selection of adhesives adapted to form the anchoring layer 3.

Still further, if at least one of a room-temperature-setting and energy ray-setting adhesives is used as an adhesive adapted to form the anchoring layer 3, it is possible to manufacture the photoelectric conversion element module without causing thermal stress to the photoelectric conversion element 1 in the setting process of the adhesive. More specifically, it is possible to manufacture the photoelectric conversion element module without applying a temperature in excess of their heat-resistant temperatures to the sensitizing dye 23b, electrolyte layer 24, sealant 27 and other members made of organic substances that form the photoelectric conversion element 1. This prevents performance degradation and damage to the members caused by heat.

### 2. Second Embodiment

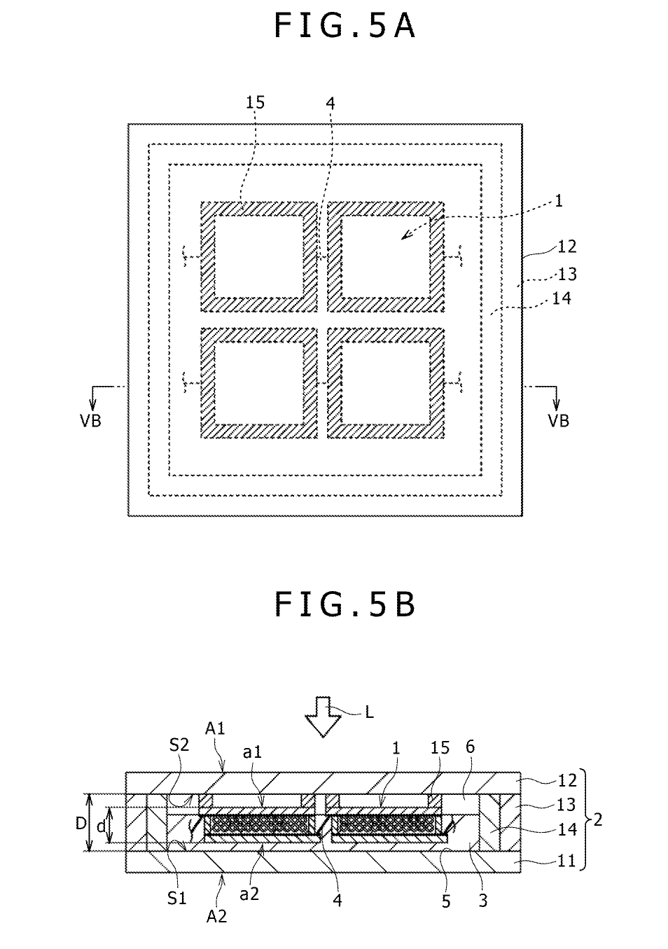

FIG. 5A is a cross-sectional view illustrating a configuration example of a photoelectric conversion element module according to a second embodiment of the present technology. FIG. 5B is a cross-sectional view along line VB-VB in FIG. 5A. The photoelectric conversion element module according to the second embodiment differs from that according to the first embodiment in that it further includes a support 15 adapted to support the incident side a1 of the photoelectric conversion element 1. The support is provided between the incident side a1 of the photoelectric conversion element 1 and the second inner side S2 of the second base material 12. The support 15 should preferably be provided between the peripheral portions of the incident side a1 of the photoelectric conversion element 1 and the second inner side S2 of the second base material 12. The reason for this is that the support 15 suppresses the reduction in amount of the incident light L falling on the incident side of the photoelectric conversion element 1. FIG. 5B illustrates an example in which the single support 15 is provided continuously on the entire peripheral portion of the incident side a1 of each of the photoelectric conversion elements 1. However, the configuration of the support 15 is not limited to this example. Instead, the plurality of supports 15 may be provided intermittently on the peripheral portion of the incident side a1 of each of the photoelectric conversion elements 1.

The support 15 is affixed to the incident side a1 of the photoelectric conversion element 1 via an affixing layer. The affixing layer contains, for example, an adhesive or agglutinant as a main ingredient. An energy ray-setting adhesive such as ultraviolet-setting adhesive can be used as an adhesive. Acrylic, rubber-based or silicon-based agglutinant, for example, can be used as an agglutinant, and a cross-linking agent may be added to the agglutinant as necessary. It should be noted that the configuration of the support 15 is not limited thereto. Instead, the support 15 may be molded integrally with the incident side a1 of the photoelectric conversion element 1 in advance. If the support 15 is configured as described above, it is possible to omit the process step of affixing the support 15 to the incident side a1 of the photoelectric conversion element 1 using an affixing layer, thus providing improved productivity of the photoelectric conversion element module.

An organic polymer, inorganic material and a composite material of an organic polymer and inorganic material, for example, can be used as the support 15. From the viewpoint of suppressing the reduction in amount of the incident light L, it is preferred to use a transparent material selected from among the above. Further, from the viewpoint of allowing the support 15 to produce a compression stress, it is preferred to use an elastic resin as the support 15. If the support 15 can produce a compression stress, the incident side a1 of the photoelectric conversion element 1 can be supported by the compression stress produced by the support 15 even in the event of a change in the operating environment temperature, thus suppressing the peeling of the photoelectric conversion element 1 off the anchoring layer 3 and providing improved reliability. If an elastic resin is used as the support 15, it is preferred to also use an elastic resin as the anchoring layer 3. Thus, the anchoring layer 3 can also produce a compression stress, thereby providing more improved reliability.

The anchoring layer 3 and support 15 should preferably satisfy relational formula (1) shown below, and more preferably relational formula (2) shown below. If these formulas are satisfied, the support 15 can support the incident side a1 of the photoelectric conversion element 1 even in the event of a change in the operating environment temperature.

Dt>(D−d)·(1+α(Tc−Tl)) (1)

Dt>>(D−d)·(1+α(Tc−Tl)) (2)

Dt: Total thickness of the anchoring layer 3 and support 15 (when open) at the steady-state operating environment temperature (Tc)

D: Distance between the first and second inner sides S1 and S2 of the housing body 2

d: Thickness of the photoelectric conversion element 1 (distance between the incident side a1 and rear side a2 of the photoelectric conversion element 1)

α: Thermal expansion coefficient of the anchoring layer 3 and support 15 (it should be noted that we assume that the linear expansion ratios of the anchoring layer 3 and support 15 are roughly equal)

Tc: Steady-state operating environment temperature

Tl: Lower limit of the operating environment temperature

It should be noted that, as for the Dt value, an appropriate value may be selected to the extent that a compression stress capable of supporting the photoelectric conversion element 1 can be produced at the lower limit of the operating environment temperature. On the other hand, the thermal expansion coefficient α is a linear expansion ratio in the direction in which the compression stress is produced. The thermal expansion coefficient α is a volume expansion ratio if the thermal expansion of the anchoring layer 3 and support 15 is isotropic.

### Modification Example

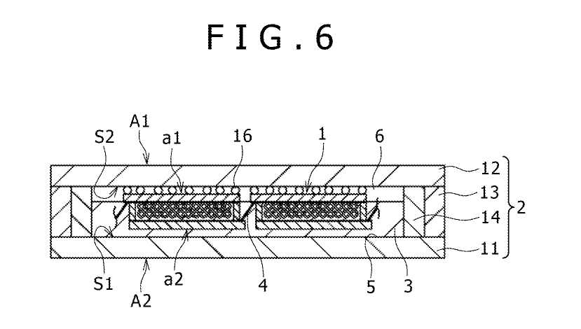

FIG. 6 is a cross-sectional view illustrating a modification example of the photoelectric conversion element module according to the second embodiment of the present technology. In this modification example, a plurality of fine particles (beads) 16 are provided as a support between the incident side a1 of the photoelectric conversion element 1 and the second inner side S2 of the second base material 12. For example, organic and inorganic fine particles may be used alone or in combination as the fine particles 16, and hollow fine particles may also be used. Optical diffusion fine particles having optical diffusion property are preferred for use as the fine particles 16. This allows the fine particles 16 to diffuse the incident light L such as sunlight diagonally falling on the incident side of the photoelectric conversion element module, thus directing the light L toward the photoelectric conversion element 1 and providing improved light utilization efficiency.

In the second embodiment, the plurality of supports 15 or fine particles 16 are provided between the incident side a1 of the photoelectric conversion element 1 and the second inner side S2 of the second base material 12, thus suppressing the peeling of the photoelectric conversion element 1 off the anchoring layer 3. This contributes to improved durability of the photoelectric conversion element module.

### 3. Third Embodiment

The third embodiment differs from the first embodiment in that the housing body 2 has one or more functions selected from a group of selective wavelength absorption, selective wavelength reflection, anti-staining, anti-reflection, diffusion and hard-coating functions. More specifically, at least one of the first or second base materials 11 and 12 making up the housing body 2 has one or more functions selected from the above group of functions. Ultraviolet absorption function (UV cutting function) and heat ray absorption function (solar shielding function) are preferred as selective wavelength absorption functions. Ultraviolet reflection function (UV cutting function) and heat ray reflection function (solar shielding function) are preferred as selective wavelength reflection functions. Water-repellent, oil-repellent and self-cleaning functions should preferably be used alone or in combination of two or more of them as anti-staining functions. Optical catalysis function, for example, is preferred as a self-cleaning function.

The above functions are imparted to at least one of the surface and inside of the housing body 2. More specifically, among configurations adapted to impart the above functions to the surface of the housing body 2 are one in which a functional layer is formed on the surface of the housing body 2 (hereinafter referred to as a first functional example) and another in which a functional structure (fine structure) is formed on the surface of the housing body 2 (hereinafter referred to as a second functional example). Among configurations adapted to impart the above functions to the inside of the housing body 2 is that in which at least one of a functional material and functional structure (fine structure) is included inside the housing body 2 (hereinafter referred to as a third functional example). A description will be given below of the first to third functional examples in sequence.

### First Functional Example

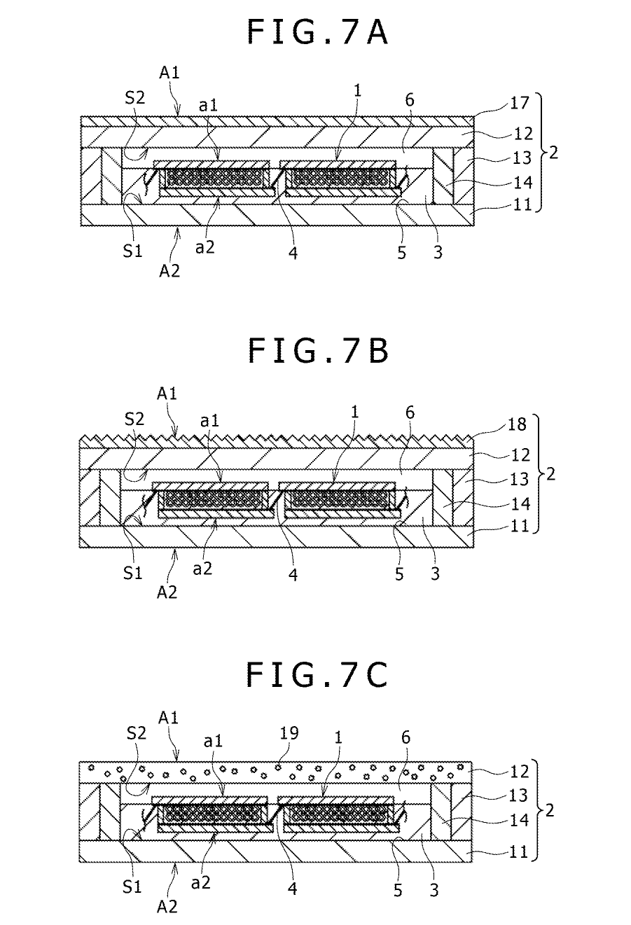

FIG. 7A is a cross-sectional view illustrating a configuration example of a photoelectric conversion element module having a functional layer on the surface of the housing body. This photoelectric conversion element module differs from that according to the first embodiment in that it further includes one or a plurality of functional layers 17 on the surface of the housing body 2.

One or more layers selected, for example, from a group of a selective wavelength absorption, selective wavelength reflection, anti-staining, anti-reflection, diffusion and hard-coating layers can be used as the functional layers 17. Ultraviolet absorption layer (UV cutting layer) and heat ray absorption layer (solar shielding function layer) are preferred as selective wavelength absorption layers. Ultraviolet reflection layer (UV cutting layer) and heat ray reflection layer (solar shielding function layer) are preferred as selective wavelength reflection layers. A layer having one or a combination of two or more of water-repellent, oil-repellent and self-cleaning functions is preferred as an anti-staining layer. Among types of layers that can be used as an anti-staining layer are optical catalysis layer and fluorine resin layer.

The functional layer 17 is provided on at least one of the first inner side (first side) S1 of the housing body 2, the second inner side (second side) S2 thereof, the incident side (third side) A1 thereof and the rear side (fourth side) A2 thereof. The plurality of functional layers 17 of different types may be provided on the surface. The side on which to provide the functional layer 17 should preferably be selected according to the type of the functional layer used. It should be noted that FIG. 7A illustrates an example in which the single functional layer 17 is provided on the incident side A1 of the housing body 2. Among methods used to form the functional layer 17 are the application and setting of a composition making up the functional layer on the surface by a wet process, the formation of a functional layer on the surface by sputtering or other dry process, and the affixation of a functional layer formed in advance in a sheet form (functional sheet) to the surface via an affixing layer.

If the photoelectric conversion element module is used as a window material such as eco-friendly glass, a heat ray absorption or reflection layer should preferably be used as the functional layer 17. In this case, the heat ray absorption or reflection layer should preferably be provided on the first inner side S1 or second inner side S2 of the housing body 2.

### Second Functional Example

FIG. 7B is a cross-sectional view illustrating a configuration example of a photoelectric conversion element module having a functional structure on the surface of the housing body. This photoelectric conversion element module differs from that according to the first embodiment in that it further includes a functional structure 18 on the surface of the housing body 2. Among fine structures that can be used as the functional structure 18 are that adapted to diffuse the incident light L (diffusion element) and that adapted to provide reduced reflectance of the incident light L and/or improved transmittance thereof (subwavelength structure).

The functional structure 18 is provided on at least one of the first inner side (first side) S1 of the housing body 2, the second inner side (second side) S2 thereof, the incident side (third side) A1 thereof and the rear side (fourth side) A2 thereof. The side on which to provide the functional structure 18 should preferably be selected according to the type of the functional structure used. It should be noted that FIG. 7B illustrates an example in which the functional structure 18 is provided on the incident side A1 of the housing body 2.

### Third Functional Example

FIG. 7C is a cross-sectional view illustrating a configuration example of a photoelectric conversion element module having a functional material or functional structure inside the housing body. This photoelectric conversion element module differs from that according to the first embodiment in that it includes at least one of a functional material and functional structure inside the housing body 2. FIG. 7C illustrates an example in which fine particles 19 are added to the inside of the housing body 2.

At least one of a functional material and functional structure is provided, for example, inside of at least one of the first and second base materials 11 and 12. Among materials that can be used as a functional material are optical diffusion fine particles adapted to diffuse light, fluorine resin material adapted to impart anti-staining property to the surface of the housing body 2, and optical catalyst. Among structures that can be used as a functional structure is a void (cavity portion) adapted to diffuse light.

### 4. Fourth Embodiment

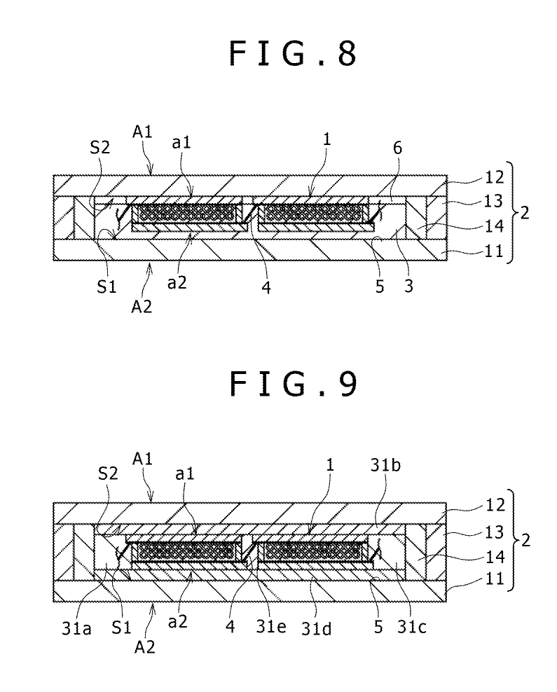

FIG. 8 is a cross-sectional view illustrating a configuration example of a photoelectric conversion element module according to a fourth embodiment of the present technology. The photoelectric conversion element module according to the fourth embodiment differs from that according to the first embodiment in that the incident side a1 of the photoelectric conversion element 1 is in close contact with the second inner side S2 of the second base material 12. It is preferred that the transparent base material 21 of the photoelectric conversion element 1 and the second base material 12 of the housing body 2 should have the same or roughly the same refractive index. The reason for this is that the reflection of the incident light L can be suppressed at the interface between the incident side a1 of the photoelectric conversion element 1 and the second inner side S2 of the second base material 12. Further, if an affixing layer having the same or roughly the same refractive index as the transparent base material 21 of the photoelectric conversion element 1 and the second base material 12 of the housing body 2 is provided therebetween, it is also possible to suppress the reflection of the incident light L at the interface between the incident side a1 of the photoelectric conversion element 1 and the second inner side S2 of the second base material 12.

In the fourth embodiment, the incident side a1 of the photoelectric conversion element 1 is in close contact with the second inner side S2 of the second base material 12. This contributes to a reduced number of interfaces of the incident side a1 of the photoelectric conversion element 1 as compared to the first embodiment, thus providing improved utilization efficiency of the incident light L.

### 5. Fifth Embodiment

FIG. 9 is a cross-sectional view illustrating a configuration example of a photoelectric conversion element module according to a fifth embodiment of the present technology. The photoelectric conversion element module according to the fifth embodiment differs from that according to the first embodiment in that spacers 31a to 31e are provided rather than the anchoring layer 3 in the housing space 5. The spacers 31a to 31e cover the surrounding of the photoelectric conversion element 1 and lie between the photoelectric conversion element 1 and housing body 2. This allows the spacers 31a to 31e to anchor the position of the photoelectric conversion element 1 in the housing body 2. Among materials that can be used as the spacers 31a to 31e is an elastic resin.

### 6. Sixth Embodiment

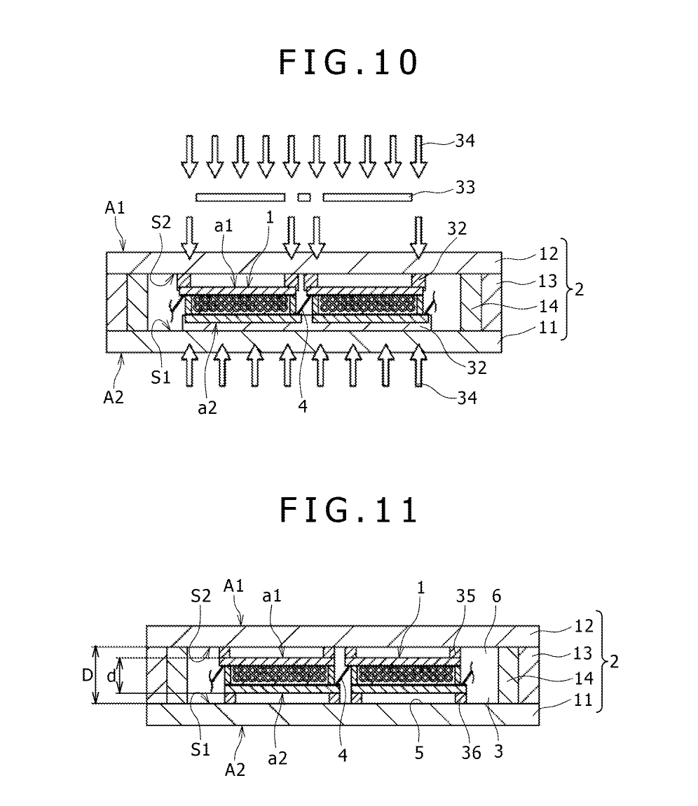

FIG. 10 is a cross-sectional view illustrating a configuration example of a photoelectric conversion element module according to a sixth embodiment of the present technology. The photoelectric conversion element module according to the sixth embodiment differs from that according to the first embodiment in that the incident side a1 of the photoelectric conversion element 1 and the second inner side S2 of the second base material 12 are affixed together, and the rear side a2 of the photoelectric conversion element 1 and the first inner side S1 of the first base material 11 are also affixed together with an energy ray-setting adhesive 32. An ultraviolet-setting adhesive is preferred for use as the energy ray-setting adhesive 32. Alternatively, a two-liquid-setting adhesive may be used rather than the energy ray-setting adhesive 32. Still alternatively, a double-sided tape having an agglutinant layer that contains, for example, an acrylic resin as a main ingredient may be used. This makes it possible to anchor the photoelectric conversion element 1 to the housing body 2 in a simpler and more convenient manner.

It is preferred to affix together the peripheral portion of the incident side a1 of the photoelectric conversion element 1 not contributing to power generation and the second inner side S2 of the second base material 12 with the energy ray-setting adhesive 32 on the incident side a1 of the photoelectric conversion element 1. In this case, it is preferred to arrange a light-shielding mask 33 above the incident side A1 of the photoelectric conversion element module so as to radiate energy rays such as ultraviolet rays onto the energy ray-setting adhesive 32 that has been applied to the peripheral portion of the incident side a1 of the photoelectric conversion element 1 for setting of the energy ray-setting adhesive 32. Energy rays such as ultraviolet rays may be radiated in a linear manner rather than radiating energy rays using the light-shielding mask 33.

If a transparent material is used as the opposed base material 26 on the rear side a2 of the photoelectric conversion element 1, it is preferred to affix together the peripheral portion of the rear side a2 of the photoelectric conversion element 1 not contributing to power generation and the first inner side S1 of the first base material 11 with the energy ray-setting adhesive 32 on the rear side a2 of the photoelectric conversion element 1. If an opaque material is used as the opposed base material 26 on the rear side a2 of the photoelectric conversion element 1, the entire rear side a2 of the photoelectric conversion element 1 and the first inner side S1 of the first base material 11 may be affixed together with the energy ray-setting adhesive 32.

### 7. Seventh Embodiment

FIG. 11 is a cross-sectional view illustrating a configuration example of a photoelectric conversion element module according to a seventh embodiment of the present technology. The photoelectric conversion element module according to the seventh embodiment differs from that according to the first embodiment in that a support 35 is provided between the peripheral portion of the incident side a1 of the photoelectric conversion element 1 and the second inner side S2 of the second base material 12, and that a support 36 is provided between the peripheral portion of the rear side a2 of the photoelectric conversion element 1 and the first inner side S1 of the first base material 11. The support 35 supports the incident side a1 of the photoelectric conversion element 1, and the support 36 the rear side a2 of the photoelectric conversion element 1.

An elastic resin adapted to produce compression stress is preferred for use as the supports 35 and 36. In this case, the supports 35 and 36 should preferably satisfy relational formula (3) shown below, and more preferably relational formula (4) shown below. If these formulas are satisfied, the supports 35 and 36 can support the photoelectric conversion element 1 even in the event of a change in the operating environment temperature.

Dt>(D−d)·(1+α(Tc−Tl)) (3)

Dt>>(D−d)·(1+α(Tc−Tl)) (4)

Dt: Total thickness of the supports 35 and 36 (when open) at the steady-state operating environment temperature (Tc)

D: Distance between the first and second inner sides S1 and S2 of the housing body 2

d: Thickness of the photoelectric conversion element 1 (distance between the incident side a1 and rear side a2 of the photoelectric conversion element 1)

α: Thermal expansion coefficient of the supports 35 and 36

Tc: Steady-state operating environment temperature

Tl: Lower limit of the operating environment temperature

It should be noted that, as for the Dt value, an appropriate value may be selected to the extent that a compression stress capable of supporting the photoelectric conversion element 1 can be produced at the lower limit of the operating environment temperature. On the other hand, the thermal expansion coefficient α is a linear expansion ratio in the direction in which the compression stress is produced. The thermal expansion coefficient α is a volume expansion ratio if the thermal expansion of the supports 35 and 36 is isotropic.

In the seventh embodiment, the photoelectric conversion element 1 is supported by the peripheral portions of the incident side a1 and rear side a2 thereof. Therefore, if the photoelectric conversion element module is disposed of, the photoelectric conversion element 1 and housing body 2 can be readily separated from each other, thus providing improved recyclability of the photoelectric conversion element module.

Although the preferred embodiments of the present technology have been specifically described above, the present technology is not limited to these embodiments, and may be modified in various ways based on the technical concept of the present technology.

For example, the configurations, methods, process steps, shapes, materials and values cited above in the embodiments are merely examples, and different configurations, methods, process steps, shapes, materials and values may be used as necessary.

Further, the above configurations, methods, process steps, shapes, materials and values may be combined without departing from the spirit of the present technology.

Still further, although examples have been described in the above embodiments in which a dye sensitized photoelectric conversion element is used as the photoelectric conversion element 1, the photoelectric conversion element 1 is not limited to these examples. Instead, for example, an amorphous photoelectric conversion element, compound semiconductor photoelectric conversion element or thin film polycrystalline photoelectric conversion element may be used.

Still further, although examples have been described in the above embodiments in which the gap portion 1b provided between the peripheral portions of the transparent base material 21 and opposed base material 26 is sealed with the sealant 27, the gap portion 1b may be filled with the anchoring layer 3 and sealed with the anchoring layer 3 rather than being sealed with the sealant 27.

Still further, one or a pluralifty of base materials may be provided on at least one of the incident side A1 and rear side A2 of the housing body 2 in the above embodiments. At this time, the base material and the incident side A1 or rear side A2 of the housing body 2 may be spaced from each other so as to form a hollow layer. The same material as used for the first base material 11 according to the first embodiment, for example, may be used as the base material.

Still further, although an example was described in the first embodiment in which the rear side of the photoelectric conversion element 1 is anchored with the anchoring layer 3 so that the hollow layer 6 is provided between the incident side of the photoelectric conversion element 1 and the second base material 12, the present technology is not limited to this example. That is, the incident side of the photoelectric conversion element 1 can be anchored with the anchoring layer 3 so that the hollow layer 6 is provided between the rear side of the photoelectric conversion element 1 and the first base material 11.

Still further, although an example was described in the second embodiment in which the rear side of the photoelectric conversion element 1 is anchored with the anchoring layer 3 so that the incident side of the photoelectric conversion element 1 is supported by the support 15 or fine particles 16, the present technology is not limited to this example. That is, the incident side of the photoelectric conversion element 1 can be anchored with the anchoring layer 3 so that the rear side of the photoelectric conversion element 1 is supported by the support 15 or fine particles 16.

Still further, although an example was described in the fourth embodiment in which the rear side of the photoelectric conversion element 1 is anchored with the anchoring layer 3 so that the incident side of the photoelectric conversion element 1 is brought into close contact with the second base material 12, the present technology is not limited to this example. That is, the incident side of the photoelectric conversion element 1 can be anchored with the anchoring layer 3 so that the rear side of the photoelectric conversion element 1 is brought into close contact with the first base material 11.

Still further, the following configurations may also be used in the present technology.

(1) A photoelectric conversion element module including:

a plurality of photoelectric conversion elements between two base materials, in which

each of the photoelectric conversion elements is anchored to one of the base materials via an anchoring layer, and

the anchoring layer covers at least part of a sealing portion of each of the photoelectric conversion elements.

(2) The photoelectric conversion element module of feature (1), in which

the photoelectric conversion element has a light incident side and a rear side opposed to the light incident side, and

the anchoring layer anchors the rear side.

(3) The photoelectric conversion element module of feature (1), in which

a hollow layer is formed between the photoelectric conversion element and the other of the base materials.

(4) The photoelectric conversion element module of feature (3), in which

the hollow layer is in a dry air, inert gas or vacuum atmosphere.

(5) The photoelectric conversion element module of any one of features (1) to (4), in which

the photoelectric conversion element is in close contact with the other base material.

(6) The photoelectric conversion element module of any one of features (1) to (5), in which

at least one of the two base materials has one or more functions selected from a group of selective wavelength absorption, selective wavelength reflection, anti-staining, anti-reflection, diffusion and hard-coating functions.

(7) The photoelectric conversion element module of any one of features (1) to (6), in which

the sealing portion is provided on the peripheral portion of the incident side, the peripheral portion of the rear side or the peripheral portion of a lateral side of the photoelectric conversion element.

(8) The photoelectric conversion element module of any one of features (1) to (6), in which

the photoelectric conversion element includes:
a transparent base material;
an opposed base material; and
a power generating element section, and

the sealing portion is provided between the peripheral portions of the transparent and opposed base materials.

(9) The photoelectric conversion element module of any one of features (1) to (8), in which

the two base materials are glass plates.

(10) The photoelectric conversion element module of any one of features (1) to (9), further including:

a sealant provided between the peripheral portions of the two base materials.

(11) The photoelectric conversion element module of any one of features (1) to (10), further including:

a shielding material provided between the peripheral portions of the two base materials to suppress the entry of moisture.

(12) The photoelectric conversion element module of any one of features (1) to (11), in which

the anchoring layer contains one or more adhesives selected from a group of thermoplastic, thermosetting, room-temperature-setting and energy ray-setting adhesives.

(13) The photoelectric conversion element module of feature (12), in which

the energy ray-setting adhesive is an ultraviolet-setting adhesive.

(14) The photoelectric conversion element module of any one of features (1) to (4) and (6) to (13), further including:

a support provided between the photoelectric conversion element and the other of the base materials.

(15) The photoelectric conversion element module of feature (14), in which

the support is provided on the peripheral portion of the light incident side of the photoelectric conversion element.

(16) The photoelectric conversion element module of any one of features (1) to (4) and (6) to (13), further including:

optical diffusion fine particles provided between the photoelectric conversion element and the other of the base materials.

(17) The photoelectric conversion element module of feature (16), in which

the optical diffusion fine particles are provided on the light incident side of the photoelectric conversion element.

(18) The photoelectric conversion element module of any one of features (1) to (17), in which

the anchoring layer lies between the photoelectric conversion element and one of the base materials, and

the elastic modulus of the anchoring layer is 500 MPa or less.

The present disclosure contains subject matter related to that disclosed in Japanese Priority Patent Application JP 2011-148611 filed in the Japan Patent Office on Jul. 4, 2011, the entire content of which is hereby incorporated by reference.

What is claimed is:

1. A photoelectric conversion element module comprising:
a plurality of photoelectric conversion elements between two base materials, wherein
each of the photoelectric conversion elements is anchored to one of the base materials via an anchoring layer, and
the anchoring layer covers at least part of a sealing portion of each of the photoelectric conversion elements.

2. The photoelectric conversion element module according to claim 1, wherein
the photoelectric conversion element has a light incident side and a rear side opposed to the light incident side, and
the anchoring layer anchors the rear side.

3. The photoelectric conversion element module according to claim 1, wherein
a hollow layer is formed between the photoelectric conversion element and the other of the base materials.

4. The photoelectric conversion element module according to claim 3, wherein
the hollow layer is in a dry air, inert gas or vacuum atmosphere.

5. The photoelectric conversion element module according to claim 1, wherein
the photoelectric conversion element is in close contact with the other base material.

6. The photoelectric conversion element module according to claim 1, wherein
at least one of the two base materials has one or more functions selected from a group of selective wavelength absorption, selective wavelength reflection, anti-staining, anti-reflection, diffusion and hard-coating functions.

7. The photoelectric conversion element module according to claim 1, wherein
the sealing portion is provided on the peripheral portion of an incident side, the peripheral portion of a rear side or the peripheral portion of a lateral side of the photoelectric conversion element.

8. The photoelectric conversion element module according to claim 1, wherein
the photoelectric conversion element includes:
a transparent base material;
an opposed base material; and
a power generating element section, and
the sealing portion is provided between the peripheral portions of the transparent and opposed base materials.

9. The photoelectric conversion element module according to claim 1, wherein
the two base materials are glass plates.

10. The photoelectric conversion element module according to claim 1, further comprising:
a sealant provided between the peripheral portions of the two base materials.

11. The photoelectric conversion element module according to claim 10, further comprising:
a shielding material provided between the peripheral portions of the two base materials to suppress the entry of moisture.

12. The photoelectric conversion element module according to claim 1, wherein
the anchoring layer contains one or more adhesives selected from a group of thermoplastic, thermosetting, room-temperature-setting and energy ray-setting adhesives.

13. The photoelectric conversion element module of claim 12, wherein
the energy ray-setting adhesive is an ultraviolet-setting adhesive.

14. The photoelectric conversion element module according to claim 1, further comprising:
a support provided between the photoelectric conversion element and the other of the base materials.

15. The photoelectric conversion element module according to claim 14, wherein
the support is provided on the peripheral portion of a light incident side of the photoelectric conversion element.

16. The photoelectric conversion element module according to claim 1, further comprising:
optical diffusion fine particles provided between the photoelectric conversion element and the other of the base materials.

17. The photoelectric conversion element module according to claim 16, wherein
the optical diffusion fine particles are provided on a light incident side of the photoelectric conversion element.

18. The photoelectric conversion element module according to claim 1, wherein
the anchoring layer lies between the photoelectric conversion element and one of the base materials, and
the elastic modulus of the anchoring layer is 500 MPa or less.
